(19) United States
(12) Patent Application Publication
(10) Pub. No.: US 2024/0172492 A1
(43) Pub. Date: May 23, 2024

(54) DISPLAY PANEL

(71) Applicant: Shenzhen China Star Optoelectronics Semiconductor Display Technology Co., Ltd., Shenzhen, Guangdong (CN)

(72) Inventor: Xi XIAO, Shenzhen, Guangdong (CN)

(73) Assignee: Shenzhen China Star Optoelectronics Semiconductor Display Technology Co., Ltd., Shenzhen, Guangdong (CN)

(21) Appl. No.: 17/779,227

(22) PCT Filed: May 17, 2022
(86) PCT No.: PCT/CN2022/093288

§ 371 Date: May 24, 2022

(30) Foreign Application Priority Data
Apr. 22, 2022 (CN) 202210430436.9

(51) Int. Cl. H10K 59/126; H10K 59/12

(52) U.S. Cl. CPC H10K 59/126; H10K 59/1201

(57) ABSTRACT

Embodiments of the present disclosure disclose a display panel. The display panel includes a substrate, a light shielding layer, a gate layer, a source/drain layer, and a shielding protection layer, where a plurality of grating slots are formed among the light shielding layer, the gate layer, and the source/drain layer, the shielding protection layer includes a body portion and an extension portion connected to the body portion, where, the extension portion is configured to cover at least one of grating slots; The grating slots are shielded by the extension portion to avoid a grating effect and reduce a ghost phenomenon.

### TECHNICAL FIELD

The present disclosure relates to a display technology field, and more particularly to a display panel.

### BACKGROUND

Referring to FIGS. 1 and 2, pixels are generally divided into a transparent part and a non-transparent part in an existing display panel, especially for a display panel with double-sided display or transparent display. The non-transparent part includes wirings such as a light shielding layer, a gate layer, a source/drain layer, and a body part, and the transparent part includes an active layer, a capacitor, and an anode.

Meanwhile, small transparent regions are formed between the wirings such as the light shielding layer 20, the gate layer 60, and the source/drain layer 80. The small transparent regions form grating slots 6, and a diffraction effect is likely to occur, which causes a ghost phenomenon of an object seen through the transparent display panel.

### Technical Problems

Therefore, the existing display panel has a technical problem of the ghost phenomenon.

### Technical Solutions to the Problems

An Embodiment of the present disclosure provides a display panel, which can alleviate a technical problem of the ghost phenomenon in the existing display panel.

An embodiment of the present disclosure provides a display panel including:

a substrates;

a TFT (Thin Film Transistor) device, wherein the TFT device is disposed above the substrate, the TFT device includes a light shielding layer disposed above the substrate, a gate layer disposed on one side of the light shielding layer away from the substrate, a source/drain layer, and a passivation layer disposed on the source/drain layer, the source/drain layer includes a source and a drain, the source drain layer is disposed on one side of the gate layer away from the substrate; and

a flat layer, wherein the flat layer is disposed on the passivation layer;

a light emitting device, wherein the light emitting device includes an anode disposed on the flat layer, a via hole is disposed on one side of the source away from the substrate, which is formed through the flat layer and the passivation layer, and the anode is electrically connected to the source by the via hole; and

a shielding protection layer including a body portion and an extension portion connected to the body portion, wherein, the body portion is disposed in the via hole and configured to cover the source;

wherein, a plurality of grating slots are formed among the light shielding layer, the gate layer, and the source/drain layer in a thickness direction of the display panel, and the extension portion is configured to cover at least one of the grating slots.

Alternatively, in some embodiments of the present disclosure, a width of the body portion is the same as a width of the extension portion.

Alternatively, in some embodiments of the present disclosure, the display panel further includes data lines disposed in a first direction and scanning lines disposed in a second direction, wherein, in the first direction, a length of the body portion is the same as a length of the extension portion.

Alternatively, in some embodiments of the present disclosure, an orthographic projection of the shielding protection layer on the substrate covers an orthographic projection of the TFT device on the substrate.

Alternatively, in some embodiments of the present disclosure, there is an overlapping region between the orthographic projection of the extension portion on the substrate and the orthographic projection of the data lines or the scanning lines on the substrate.

Alternatively, in an embodiment of the present disclosure, the TFT device further includes an active layer, wherein the active layer is disposed on one side of the light shielding layer away from the substrate, and a preparation material of the active layer is a transparent indium gallium zinc oxide material.

Alternatively, in some embodiments of the present disclosure, the extension portion has a grid-like structure, and includes a light blocking portion and a hollow portion, the light blocking portion is configured to cover the grating slots in the thickness direction of the layers, and the hollow portion is disposed in correspondence with the light shielding layer, the gate layer, and the source/drain layer.

Alternatively, in some embodiments of the present disclosure, the conductive performance of the body portion is greater than the conductive performance of the extension portion.

Alternatively, in some embodiments of the present disclosure, the TFT device is disposed in a staggered manner with the light emitting device. The light emitting device further includes a light emitting layer disposed on one side of the anode away from the substrate, and a cathode disposed on one side of the light emitting layer away from the substrate. Preparation materials of the anode and the cathode are both transparent materials.

Alternatively, in some embodiments of the present disclosure, the display panel further includes a surface cathode lapping region, in which the shielding protection layer and the cathode are disposed in parallel.

Alternatively, in some embodiments of the present disclosure, the shielding protection layer further includes an auxiliary electrode portion located in the surface cathode lapping region, wherein the auxiliary electrode portion is disposed at intervals from the body portion and the extension portion, and configured to lap with the cathode, so that an impedance of the cathode is reduced.

Alternatively, in some embodiments of the present disclosure, the shielding protection layer is disposed in a profiled structure in the surface cathode lapping region.

Alternatively, in some embodiments of the present disclosure, the shielding protection layer is disposed on a same layer as the anode.

Alternatively, in some embodiments of the present disclosure, the anode is a single-layer structure, and a preparation material of the anode is indium tin oxide.

Alternatively, in some embodiments of the present disclosure, the shielding protection layer is disposed on one surface of the passivation layer away from the substrate.

Alternatively, in some embodiments of the present disclosure, the preparation material of the shielding protection layer includes at least one of molybdenum, aluminum, or titanium.

Alternatively, in some embodiments of the present disclosure, all of the preparation materials of the light shielding layer, the gate layer, and the source/drain layer are light shielding materials.

Alternatively, in some embodiments of the present disclosure, the preparation material of the shielding protection layer is the same as the preparation material of the source/drain layer.

Alternatively, in some embodiments of the present disclosure, the shielding protection layer has a thickness ranging from 20 nm to 200 nm.

An embodiment of the present disclosure provides a method for preparing a display panel, including:

providing an array substrate, wherein the array substrate includes a source/drain layer and a passivation layer disposed on the source/drain layer;

preparing a flat layer on the array substrate to form a via hole passing through the flat layer and the passivation layer;

preparing a shielding protection layer on one side of the passivation layer away from the substrate, wherein the shielding protection layer is configured to cover at least one grating slot; and

preparing an anode, a light emitting layer, a cathode, and an encapsulation layer on one side of the flat layer away from the substrate.

### Beneficial Effects

By disposing a shielding protection layer including a body portion and an extension portion formed by extending the body portion and disposing the extension portion to cover at least one of the grating slots to shield the grating slot, the technical problem that the ghost phenomenon exists on the existing display panel can be alleviated.

### BRIEF DESCRIPTION OF THE DRAWINGS

In order to more clearly illustrate the technical solutions in embodiments of the present disclosure, the accompanying drawings depicted in the description of the embodiments will be briefly described below. It will be apparent that the accompanying drawings in the following description are merely some embodiments of the present disclosure, and other drawings may be obtained from these drawings without creative effort by those skilled in the art.

FIG. 1 is a top view of an existing display panel;

FIG. 2 is a sectional view taken alone the line A-A of the existing display panel;

FIG. 3 is a top view of a display panel according to an embodiment of the present disclosure;

FIG. 4 is a sectional view taken alone the line B-B of the display panel according to an embodiment of the present disclosure;

FIG. 5 is another sectional view of the display panel according to an embodiment of the present disclosure; and

FIG. 6 is a flowchart of a method of manufacturing a display panel according to an embodiment of the present disclosure.

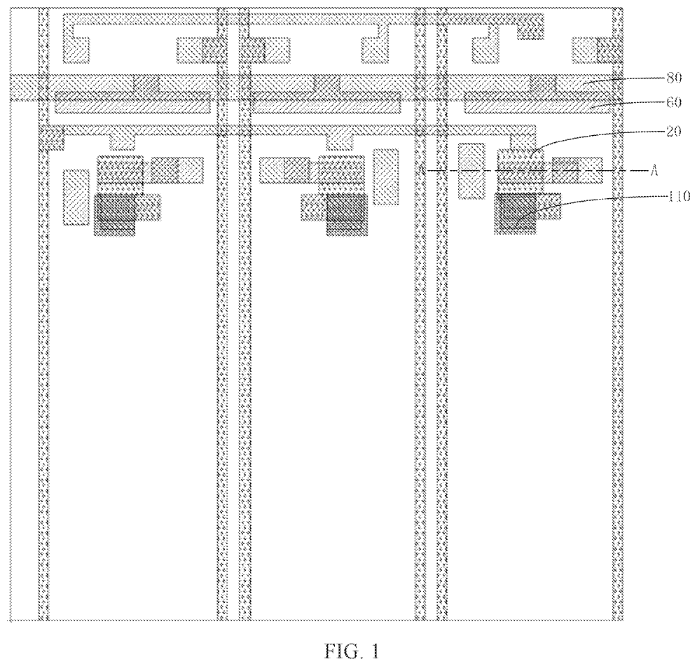

### DESCRIPTION OF REFERENCE SIGNS

| reference | | reference | |
|---|---|---|---|
| sign | component name | sign | component name |
| 1 | light emitting region | 2 | spacing region |
| 3 | scanning line | 4 | Data line |
| 5 | TFT device | 6 | grating slot |
| 10 | substrate | 20 | light shielding layer |
| 30 | buffer layer | 40 | active layer |
| 50 | gate insulation layer | 60 | gate layer |
| 70 | interlayer insulation layer | 80 | source/drain layer |
| 90 | passivation layer | 100 | flat layer |
| 110 | shielding protection layer | 120 | anode |
| 130 | light emitting layer | 140 | cathode |
| 150 | encapsulation layer | 801 | source |
| 802 | drain | 1101 | body portion |
| 1102 | extension portion | 160 | pixel definition layer |

### EMBODIMENTS OF THE PRESENT DISCLOSURE

Technical solutions in embodiments of the present disclosure will be clearly and completely described below in conjunction with drawings in the embodiments of the present disclosure. It is apparent that the described embodiments are only a part of embodiments of the present disclosure, rather than all the embodiments. Based on the embodiments in the present disclosure, all other embodiments obtained by those skilled in the art without creative work fall within the protection scope of the present disclosure. In addition, it should be understood that the specific implementations described here are only used to illustrate and explain the present disclosure, and are not used to limit the present disclosure. In the present disclosure, unless otherwise stated, directional words used such as “upper” and “lower” generally refer to the upper and lower directions of the device in actual use or working state, and specifically refer to the drawing directions in the drawings; and “inner” and “outer” refer to the outline of the device.

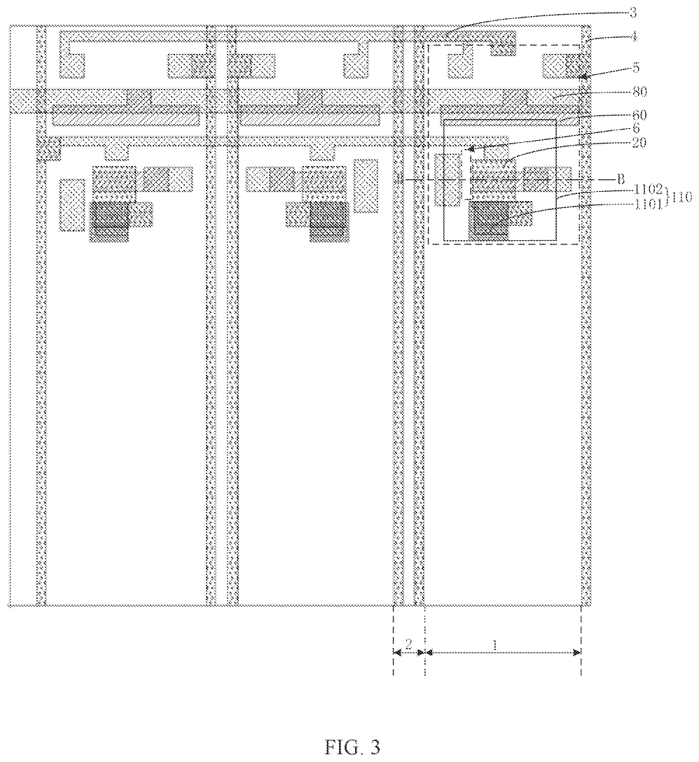

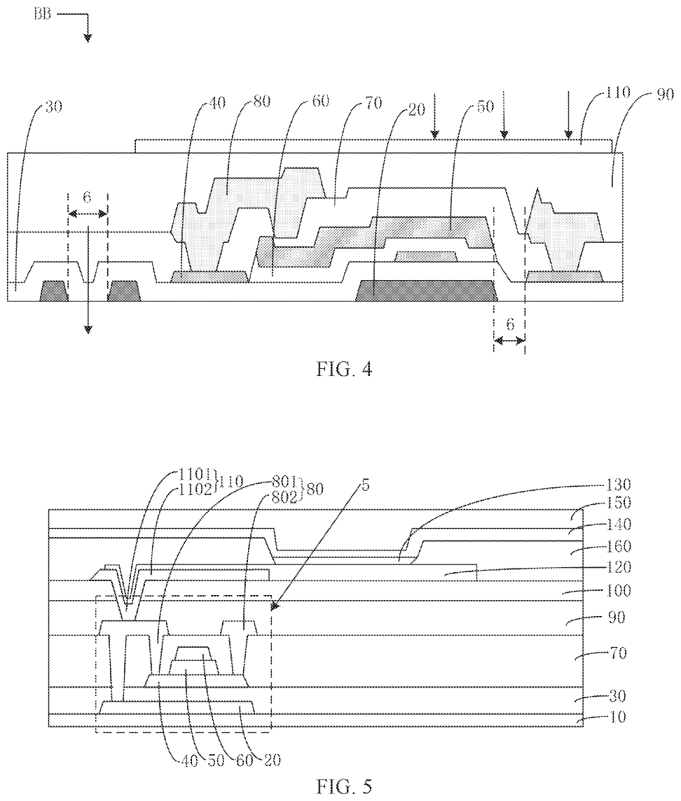

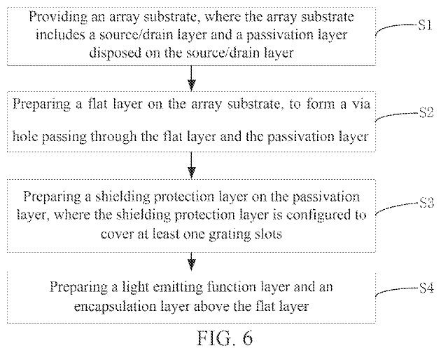

Referring to FIG. 3 and FIG. 4, a display panel provided in an embodiment of the present disclosure includes a substrate 10, a TFT device 5, a flat layer 100, a light emitting device, and a shielding protection layer 110. The TFT device 5 is disposed above the substrate 10. The TFT device 5 includes a light shielding layer 20 disposed above the substrate 10, a gate layer 60 disposed on one side of the light shielding layer 20 away from the substrate, a source/drain layer 80, and a passivation layer 90 disposed on the source/drain layer 80. The source/drain layer 80 includes a source 801 and a drain 802. The source/drain layer 80 is disposed on one side of the gate layer 60 away from the substrate. The flat layer 100 is disposed on the passivation layer 90. The light emitting device includes an anode 120 disposed on the flat layer 100. A via hole is disposed on one side of the source 801 away from the substrate, which is formed through the flat layer 100 and the passivation layer 90. The shielding protection layer 110 includes a body portion 1101 and an extension portion 1102 connected to the body portion 1101. The body portion 1101 is disposed in the via hole and configured to cover the source 801. A preparation material of the shielding protection layer 110 is a light shielding material. A plurality of grating slots 6 are formed among the light shielding layer 20, the gate layer 60, and the source/drain layer 80 in a thickness direction of the display panel, and the extension portion 1102 is configured to cover at least one of the grating slots 6.

The anode 120 may be electrically connected to the source 81 by the via hole. Further, the body portion 1101 is provided on one surface of the source 801 away from the substrate 10, where, one end of the body portion 1101 is connected to the anode 120 and opposite end of the body portion 1101 is connected to the source node 801.

The plurality of grating slots 6 are formed among the light shielding layer 20, the gate layer 60, and the source/drain layer 80 and prone to produce a ghost phenomenon.

A coverage area of the grating slots 6 may be further increased by disposing the extension portion 1102, so that diffraction of the grating slots 6 among metal wirings of the light shielding layer 20, the gate layer 60, and the source/drain layer 80 can be reduced, thereby improving a display effect.

The TFT device 5 further includes a buffer layer 30, a gate insulation layer 50, and an interlayer insulation layer 70. The buffer layer 30 is disposed on the substrate 10 and the light shielding layer 20. The gate insulation layer 50 is disposed on an active layer 40. The interlayer insulation layer 70 is disposed on the gate layer 60 and the buffer layer 30.

A pixel definition layer 160 is further disposed on the flat layer 100.

It may be understood that occurrence of the ghost phenomenon can be effectively alleviated by shielding the grating slots 6. Further, the body portion 1101 is disposed in the via hole and configured to cover the source 801. By extending the body portion 1101 to the grating slots 6 and shielding at least one of the grating slot 6, occurrence of the ghost phenomenon can be reduced.

The present disclosure can alleviate a technical problem that the ghost phenomenon exists on the existing display panel by extending the body portion 1101 to form an extension portion 1102 and disposing the extension part 1102 to cover at least one of the grating slots 6 to shield the grating slot 6.

Technical solutions of the present disclosure will be described now in conjunction with specific embodiments of the present disclosure.

In an embodiment, the shielding protection layer 110 may be disposed on the source 801 and the passivation layer 90.

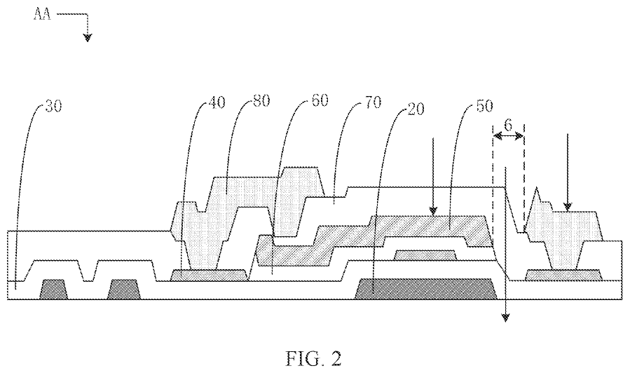

In another embodiment, referring to FIG. 2, the shielding protection layer 110 may be further disposed on the source 801 and the flat layer 100.

In an embodiment, the display panel further includes data lines 4 disposed in a first direction and scanning lines 3 disposed in a second direction, where a width of the body portion 1101 in the second direction is the same as a width of the extension portion 1102 in the second direction.

The display panel includes a plurality of pixel units arranged regularly, and any of the pixel units is disposed between adjacent data lines 4 and adjacent scanning lines 3.

A length of the extension portion 1102 may be the same as a length of the body portion 1101 in the first direction.

The pixel unit includes three sub-pixel units of different colors, where the sub-pixel unit includes a light emitting region 1, and a spacing region 2 is included between adjacent sub-pixel units.

In the second direction, a width of the light emitting region 1 may be 51.5 microns, and a width of the spacing region 2 may be 14 microns.

It may be understood that the extension portion 1102 is obtained by extending the body portion 1101 toward the first direction without changing the width of the body portion 1101.

In the embodiment, either the width or the length of the extension portion 1102 is the same as that of the body portion 1101, thereby simplifying a production process of the extension portion 1102 and reducing costs.

In an embodiment, referring to FIG. 4, the shielding protection layer 110 may be further disposed on one surface of the passivation layer 90 away from the substrate 10.

In an embodiment, referring to FIG. 5, an orthographic projection of the shielding protection layer 110 on the substrate 10 covers an orthographic projection of the TFT device 5 on the substrate 10.

The orthographic projection of the shielding protection layer 110 on the substrate 10 can completely coincide with an orthographic projection of the TFT device 5 on the substrate 10.

It may be understood that the plurality of grating slots 6 exist among the metal wirings of the light shielding layer 20, the gate layer 60, and the source/drain layer 80 of the TFT device 5, and the TFT device 5 is completely covered, so that all grating slots 6 in the TFT device 5 are completely shielded, thereby further improving an effect of reducing the ghost phenomenon.

In the embodiment, in the thickness direction of the display panel, the shielding layer 110 is configured to cover the TFT device 5 and completely shield the grating slots 6 in the TFT device 5, thereby reducing the ghost phenomenon.

In an embodiment, referring to FIG. 5, the shielding protection layer 110 is disposed on a same layer as the anode 120.

In an embodiment, there is an overlapping region between the orthographic projection of the extension portion 1102 on the substrate 10 and the orthographic projection of the data lines 4 or the scanning lines 3 on the substrate 10.

Grating slots 6 also exist among the data lines 4, the scanning lines 3, and the metal wrings.

It may be understood that the body portion 1101 and the extension portion 1102 may be extended in either the first direction or the second direction, which breaks a periodic structure of longitudinal wrings, thereby reducing the grating effect.

In the embodiment, the extension portion 1102 is further extended in the first direction and the second direction, so that the extension portion 1102 is configured to cover a portion of the data lines 4 and the scanning lines 3, and further shield the grating slots 6 around the data lines 4 and the scanning lines 3, thereby reducing the grating effect.

In an embodiment, the TFT device 5 is disposed in a staggered manner with the light emitting device. The light emitting device further includes a light emitting layer 130 disposed on one side of the anode 120 away from the substrate, and a cathode 140 disposed on one side of the light emitting layer 130 away from the substrate. Preparation materials of the anode 120 and the cathode 140 are both transparent materials.

The anode 120 is a single-layer structure, and a material for preparing the anode 120 may be indium tin oxide.

The display panel may be a two-sided display panel.

No reflective layer or semi-reflective layer is disposed on one side of the light emitting device away from the substrate and/or on opposite side of the light emitting device close to the substrate.

It may be understood that the TFT device 5 is disposed in a staggered manner with the light emitting device, and the TFT device 5 does not shield light emitted from the light emitting device toward the substrate 10.

In the embodiment, the grating effect of the two-sided display panel is more severe than that of one-sided display panel. With a structural design of the shielding protection layer 110, the grating effect is reduced, thereby further reducing the ghost phenomenon of transparent display.

In an embodiment, the TFT device 5 further includes an active layer 40, where the active layer 40 is disposed on one side of the light shielding layer 20 away from the substrate, and a preparation material of the active layer 40 is a transparent indium gallium zinc oxide material.

In an embodiment, the preparation materials of the light shielding layer 20, the gate layer 60, and the source/drain layer 80 are all light shielding materials.

In an embodiment, the preparation material of the shielding protection layer 110 is the same as that of the source/drain layer 80.

The shielding protection layer 110 and the source/drain layer 80 may be prepared in a same step.

In the embodiment, manufacturing costs of the display panel can be also reduced by simplifying a manufacturing process of the shielding protection layer 110.

In an embodiment, the preparation material of the shielding protection layer 110 includes at least one of molybdenum, aluminum, or titanium.

The shielding protection layer 110 may further include another opaque metal material.

The conductive performance of the body portion 1101 may be greater than that of the extension portion 1102.

It may be understood that the body portion 1101 needs to ensure certain conductive performance. Therefore, the conductive performance of the body portion 1101 may be greater than that of the source 801 or the anode 120.

In the embodiment, a material of the shielding protection layer 110 is limited, so that the shielding protection layer 110 has certain conductive performance while having the light shielding performance, thereby improving stability of the display panel.

In an embodiment, the shielding protection layer 110 has a thickness ranging from 20 nm to 200 nm.

In an embodiment, the extension portion 1102 has a grid-like structure.

The extension portion 1102 may include a light blocking portion and a hollow portion.

The light blocking portion and the grating slot 6 are disposed in correspondence with each other. Further, the light blocking portion is configured to cover the grating slot 6 in the thickness direction of the display panel.

The hollow portion may be disposed in correspondence with the metal wirings of the light shielding layer 20, the gate layer 60, and the source/drain layer 80.

It should be noted that a range of an orthographic projection of the grating gap 6 covered by the light blocking portion on the substrate 10 is extremely small, and an impact on the transmittance of the display panel is extremely small.

In the embodiment, the extension portion 1102 is configured to have a grid-like structure, so that a technical effect of reducing the ghost phenomenon is achieved by shielding the grating slots 6. Meanwhile, an impact on the transmittance of the display panel is reduced by disposing the hollow portion.

In an embodiment, the display panel further includes a surface cathode 140 lapping region, in which the cathode 140 is disposed in contact with the shielding protection layer 110.

Specifically, the shielding protection layer further includes an auxiliary electrode portion located in the surface cathode lapping region, where the auxiliary electrode portion is disposed at intervals from the body portion and the extension portion, and configured to lap with the cathode, thereby reducing a cathode impedance.

The cathode 140 and the shielding protection layer 110 may be surface-contacted.

It may be understood that the shielding protection layer 110 and the cathode 140 are disposed in parallel, which can reduce a resistance of the cathode 140, further reduce a loss of signal transmission of the cathode 140 on the display panel, and improve stability of the display panel.

In an embodiment, the shielding protection layer 110 may be disposed in a profiled structure in the surface cathode 140 lapping region.

In the embodiment, the profiled structure may increase a contact area with the cathode 140, reduce a contact impedance, and further reduce a resistance of the cathode 140.

Referring to FIG. 3, a method for preparing a display panel disclosed in an embodiment of the present disclosure includes:

S1: providing an array substrate, where the array substrate includes a source/drain layer 80 and a passivation layer 90 disposed on the source/drain layer 80;

S2: preparing a flat layer 100 on the array substrate to form a via hole passing through the flat layer 100 and the passivation layer 90;

S3: preparing a shielding protection layer 110 on one side of the passivation layer 90 away from the substrate 10, where the shielding protection layer 110 is configured to cover at least one of grating slots 6; and

S4: preparing an anode 120, a light emitting layer 130, a cathode 140, and an encapsulation layer 150 on one side of the flat layer 100 away from the substrate.

The array substrate includes a light shielding layer 20, a gate layer 60, and a source/drain layer 80, and a plurality of grating slots 6 are formed among metal wirings of the light shielding layer 20, the gate layer 60, and the source/drain layer 80.

The shielding protection layer 110 includes a body portion 1101 and an extension portion 1102. The body portion 1101 is located in the via hole and configured to cover the source 801. The extension portion 1102 is connected to the body portion 1101. The shielding protection layer 110 is configured to cover at least one of the grating slots 6.

The array substrate includes a source/drain layer 80 and a passivation layer 90 disposed on the source/drain layer 80.

The via hole is located on one side of the source 801 away from the substrate.

Embodiments of the present disclosure further provide a display apparatus and a display module. Both the display module and the display apparatus include the foregoing display panel, which is not repeatedly described herein.

The display panel provided in the embodiment includes a substrate, a TFT device, a flat layer, a light emitting device, and a shielding protection layer. The TFT device is disposed above the substrate. The TFT device includes a light shielding layer disposed above the substrate, a gate layer disposed on one side of the light shielding layer away from the substrate, a source/drain layer, and a passivation layer disposed on the source/drain layer. The source/drain layer includes a source and a drain. The source/drain layer is disposed on one side of the gate layer away from the substrate. The flat layer is disposed on the passivation layer. The light emitting device includes an anode disposed on the flat layer. A via hole is disposed on one side of the source away from the substrate, which is formed through the flat layer and the passivation layer. The anode is electrically connected to the source by the via hole. The shielding protection layer includes a body portion and an extension portion connected to the body portion. The body portion is disposed in the via hole and configured to cover the source. A preparation material of the shielding protection layer is a light shielding material. A plurality of grating slots are formed among the light shielding layer, the gate layer, and the source/drain layer in a thickness direction of the display panel, and the extension portion is configured to cover at least one of the grating slots. By extending the body portion to form an extension portion and disposing the extension part to cover at least one of the grating slots to shield the grating slot, the technical problem that the ghost phenomenon exists on the existing display panel can be alleviated.

In the foregoing embodiments, descriptions of the embodiments are emphasized. A portion that is not described in detail in an embodiment may refer to related descriptions in another embodiment.

The display panel and the method for preparing the display panel provided in the embodiments of the present disclosure are described in detail above. Specific embodiments are used herein to describe a principle and an implementation of the present disclosure. The description of the foregoing embodiments is merely used to help understand a method and a core idea of the present disclosure. In addition, a person skilled in the art may make changes in a specific implementation manner and an application scope according to an idea of the present disclosure. In conclusion, content of this specification should not be construed as a limitation on the present disclosure.

What is claimed is:

1. A display panel, comprising:
a substrate;
a Thin Film Transistor, i.e. TFT device, wherein the TFT device is disposed above the substrate, the TFT device includes a light shielding layer disposed above the substrate, a gate layer disposed on one side of the light shielding layer away from the substrate, a source/drain layer, and a passivation layer disposed on the source/drain layer, wherein the source/drain layer includes a source and a drain, and the source drain layer is disposed on one side of the gate layer away from the substrate; and
a flat layer, wherein the flat layer is disposed on the passivation layer;
a light emitting device, wherein the light emitting device includes an anode disposed on the flat layer, a via hole is disposed on one side of the source away from the substrate, which is formed through the flat layer and the passivation layer, and the anode is electrically connected to the source by the via hole; and
a shielding protection layer including a body portion and an extension portion connected to the body portion, wherein, the body portion is disposed in the via hole and configured to cover the source;
wherein, a plurality of grating slots are formed among the light shielding layer, the gate layer, and the source/drain layer in a thickness direction of the display panel, and the extension portion is configured to cover at least one of the grating slots.

2. The display panel of claim 1, wherein, a width of the body portion is the same as a width of the extension portion.

3. The display panel of claim 2, wherein the display panel further includes data lines disposed in a first direction and scanning lines disposed in a second direction, wherein, in the first direction, a length of the body portion is the same as a length of the extension portion.

4. The display panel of claim 2, wherein an orthographic projection of the shielding protection layer on the substrate covers an orthographic projection of the TFT device on the substrate.

5. The display panel of claim 3, wherein an overlapping region between the orthographic projection of the extension portion on the substrate and the orthographic projection of the data lines or the scanning lines on the substrate is formed.

6. The display panel of claim 1, wherein the TFT device further includes an active layer, wherein the active layer is disposed on one side of the light shielding layer away from the substrate, and a preparation material of the active layer is a transparent indium gallium zinc oxide material.

7. The display panel of claim 6, wherein, the extension portion has a grid-like structure, and includes a light blocking portion and a hollow portion, the light blocking portion is configured to cover the grating slots in the thickness direction of the layers, and the hollow portion is disposed in correspondence with the light shielding layer, the gate layer, and the source/drain layer.

8. The display panel of claim 1, wherein the conductive performance of the body portion is greater than the conductive performance of the extension portion.

9. The display panel of claim 1, wherein the TFT device is disposed in a staggered manner with the light emitting device, the light emitting device further includes a light emitting layer disposed on one side of the anode away from the substrate, and a cathode disposed on one side of the light emitting layer away from the substrate, and preparation materials of the anode and the cathode are both transparent materials.

10. The display panel of claim 1, wherein the display panel further includes a surface cathode lapping region, in which the shielding protection layer and the cathode are disposed in parallel.

11. The display panel of claim 10, wherein the shielding protection layer further includes an auxiliary electrode portion located in the surface cathode lapping region, wherein the auxiliary electrode portion is disposed at intervals with the body portion and the extension portion, and configured to lap with the cathode, so that an impedance of the cathode is reduced.

12. The display panel of claim 11, wherein the shielding protection layer is disposed in a profiled structure in the surface cathode lapping region.

13. The display panel of claim 1, wherein the shielding protection layer is disposed on a same layer as the anode.

14. The display panel of claim 13, wherein the anode is a single-layer structure, and a preparation material for the anode is indium tin oxide.

15. The display panel of claim 1, wherein the shielding protection layer is disposed on one surface of the passivation layer away from the substrate.

16. The display panel of claim 1, wherein the preparation material of the shielding protection layer includes at least one of molybdenum, aluminum, or titanium.

17. The display panel of claim 1, wherein all of the preparation materials of the light shielding layer, the gate layer, and the source/drain layer are light shielding materials.

18. The display panel of claim 17, wherein the preparation material of the shielding protection layer is the same as the preparation material of the source/drain layer.

19. The display panel of claim 1, wherein the shielding protection layer has a thickness ranging from 20 nm to 200 nm.

20. A method for preparing a display panel, comprising:
providing an array substrate, wherein the array substrate includes a source/drain layer and a passivation layer disposed on the source/drain layer;
preparing a flat layer on the array substrate to form a via hole passing through the flat layer and the passivation layer;
preparing a shielding protection layer on one side of the passivation layer away from the substrate, wherein the shielding protection layer is configured to cover at least one grating slot; and
preparing an anode, a light emitting layer, a cathode, and an encapsulation layer on one side of the flat layer away from the substrate.
